(19) United States
(12) Patent Application Publication
(10) Pub. No.: US 2026/0162740 A1
(43) Pub. Date: Jun. 11, 2026

(54) MEMORY DEVICE AND PROGRAM OPERATION THEREOF

(71) Applicant: Yangtze Memory Technologies Co., Ltd., Wuhan (CN)

(72) Inventors: Yang Zhang, Wuhan (CN); Zhijiu Zhu, Wuhan (CN); Peicheng Chen, Wuhan (CN); Masao Kuriyama, Wuhan (CN)

(21) Appl. No.: 19/011,441

(22) Filed: Jan. 6, 2025

(30) Foreign Application Priority Data
Dec. 9, 2024 (CN) 202411804003.0

(51) Int. Cl. G11C 16/34; G11C 16/04; G11C 16/12

(52) U.S. Cl. CPC G11C 16/3459; G11C 16/0483; G11C 16/12

(57) ABSTRACT

In certain aspects, a memory device includes a first memory plane including memory cells and word lines respectively coupled to rows of the memory cells, and a peripheral circuit coupled to the first memory plane through the word lines. The peripheral circuit is configured to, in a last loop of a program operation on the first memory plane, after applying a verify voltage to a select word line of the word lines, ramp up a voltage on the select word line from a first supply voltage (Vdd) to a pass voltage, and ramp down the voltage on the select word line of the word lines from the pass voltage to the first supply voltage.

### CROSS-REFERENCE TO RELATED APPLICATIONS

This application claims the benefit of priority to Chinese Application No. 202411804003.0, filed on Dec. 9, 2024, which is hereby incorporated by reference in its entirety.

### BACKGROUND

The present disclosure relates to memory devices and operation methods thereof.

Flash memory is a low-cost, high-density, non-volatile solid-state storage medium that can be electrically erased and reprogrammed. Flash memory includes NOR Flash memory and NAND Flash memory. Various operations can be performed by Flash memory, such as read, program (write), and erase. For NAND Flash memory, an erase operation can be performed at the block level, and a program operation or a read operation can be performed at the page level.

### SUMMARY

In one aspect, a memory device includes a first memory plane including memory cells and word lines respectively coupled to rows of the memory cells, and a peripheral circuit coupled to the first memory plane through the word lines. The peripheral circuit is configured to, in a last loop of a program operation on the first memory plane, after applying a verify voltage to a select word line of the word lines, ramp up a voltage on the select word line from a first supply voltage (Vdd) to a pass voltage, and ramp down the voltage on the select word line of the word lines from the pass voltage to the first supply voltage.

In some implementations, the peripheral circuit is further configured to, in the last loop of the program operation on the first memory plane, after applying the verify voltage to the select word line, apply a bias voltage to the select word line, the bias voltage being between the first supply voltage and the pass voltage, and ramp down the voltage on the select word line from the bias voltage to the first supply voltage before ramping up the voltage on the select word line from the first supply voltage to the pass voltage.

In some implementations, the first memory plane further includes select gate transistors respectively coupled to columns of the memory cells, and a select gate line coupled to the select gate transistors. In some implementations, the peripheral circuit is coupled to the first memory plane through the select gate line and further configured to, in the last loop of the program operation on the first memory plane, ramp up a voltage on the select gate line from a second supply voltage (Vss) smaller than the first supply voltage to a select voltage, and ramp down the voltage on the select gate line from the select voltage to the second supply voltage.

In some implementations, the memory device further includes a second memory plane including memory cells and word lines respectively coupled to rows of the memory cells. In some implementations, the peripheral circuit is coupled to the first memory plane and the second memory plane and configured to start the program operation on the first memory plane and the second memory plane at a same time, and stop the program operation on the first memory plane before the second memory plane.

In some implementations, the peripheral circuit is configured to suspend the program operation on the second memory plane from a first time when the voltage on the select word line in the first memory plane starts ramping down from the bias voltage to the first supply voltage until a second time when the voltage on the select word line in the first memory plane is ramped down from the pass voltage to the first supply voltage.

In some implementations, the peripheral circuit includes string drivers respectively coupled to the word lines in the second memory plane. In some implementations, to suspend the program operation on the second memory plane, the string drivers are configured to be disabled to float voltages on the word lines in the second memory plane.

In some implementations, the peripheral circuit is further configured to apply a program voltage to the select word line of the word lines in the second memory plane after the second time.

In some implementations, the peripheral circuit is further configured to, in a last loop of the program operation on the second memory plane, after applying a verify voltage to the select word line, apply the bias voltage to the select word line, ramp down the voltage on the select word line from the bias voltage to the first supply voltage, ramp up the voltage on the select word line from the first supply voltage to the pass voltage, and ramp down the voltage on the select word line from the pass voltage to the first supply voltage.

In some implementations, the memory device further includes a third memory plane. In some implementations, the peripheral circuit is coupled to the first memory plane, the second memory plane, and the third memory plane and configured to start the program operation on the first memory plane, the second memory plane, and the third memory plane at a same time, and stop the program operation on the second memory plane before the third memory plane.

In some implementations, the peripheral circuit is configured to suspend the program operation on the third memory plane from the first time when the voltage on the select word line in the first memory plane starts ramping down from the bias voltage to the first supply voltage until the second time after the voltage on the select word line in the first memory plane is ramped down from the pass voltage to the first supply voltage, and suspend the program operation on the third memory plane from a third time when the voltage on the select word line in the second memory plane starts ramping down from the bias voltage to the first supply voltage until a fourth time after the voltage on the select word line in the second memory plane is ramped down from the pass voltage to the first supply voltage.

In some implementations, the peripheral circuit is further configured to, in the last loop of the program operation on the first memory plane, before applying the bias voltage to the select word line, apply a post-pulse voltage on the select word line of the word lines after applying the verify voltage on the select word line, ramp down the voltage on the select word line from the post-pulse voltage to the first supply voltage, and immediately ramp up the voltage on the select word line from the first supply voltage to the bias voltage.

In another aspect, a method for operating a memory device is provided. The memory device includes a first memory plane including memory cells and word lines respectively coupled to rows of the memory cells. In a last loop of a program operation on the first memory plane, after applying a verify voltage to a select word line of the word lines, a voltage on the select word line is ramped up from a first supply voltage (Vdd) to a pass voltage. The voltage on the select word line of the word lines is ramped down from the pass voltage to the first supply voltage.

In some implementations, in the last loop of the program operation on the first memory plane, after applying the verify voltage to the select word line, a bias voltage is applied to the select word line. The bias voltage is between the first supply voltage and the pass voltage. In some implementations, the voltage on the select word line is ramped down from the bias voltage to the first supply voltage before ramping up the voltage on the select word line from the first supply voltage to the pass voltage.

In some implementations, the first memory plane further includes select gate transistors respectively coupled to columns of the memory cells, and a select gate line coupled to the select gate transistors. In some implementations, in the last loop of the program operation on the first memory plane, a voltage on the select gate line is ramped up from a second supply voltage (Vss) smaller than the first supply voltage to a select voltage, and the voltage on the select gate line is ramped down from the select voltage to the second supply voltage.

In some implementations, the memory device further includes a second memory plane including memory cells and word lines respectively coupled to rows of the memory cells. In some implementations, the program operation is started on the first memory plane and the second memory plane at a same time, and the program operation is stopped on the second memory plane before the third memory plane.

In some implementations, the program operation is suspended on the second memory plane from a first time when the voltage on the select word line in the first memory plane starts ramping down from the bias voltage to the first supply voltage until a second time when the voltage on the select word line in the first memory plane is ramped down from the pass voltage to the first supply voltage.

In some implementations, the memory device further includes string drivers respectively coupled to the word lines in the second memory plane. In some implementations, to suspend the program operation on the second memory plane, the string drivers are disabled to float voltages on the word lines in the second memory plane.

In some implementations, a program voltage is applied to the select word line of the word lines in the second memory plane after the second time.

In some implementations, in a last loop of the program operation on the second memory plane, after applying a verify voltage to the select word line, the bias voltage is applied to the select word line, the voltage on the select word line is ramped down from the bias voltage to the first supply voltage, the voltage on the select word line is ramped up from the first supply voltage to the pass voltage, and the voltage on the select word line is ramped down from the pass voltage to the first supply voltage.

In some implementations, the memory device further includes a third memory plane. In some implementations, the program operation on the first memory plane, the second memory plane, and the third memory plane are started at a same time, and the program operation is stopped on the second memory plane before the third memory plane.

In some implementations, the program operation is suspended on the third memory plane from the first time when the voltage on the select word line in the first memory plane starts ramping down from the bias voltage to the first supply voltage until the second time after the voltage on the select word line in the first memory plane is ramped down from the pass voltage to the first supply voltage. In some implementations, the program operation is suspended on the third memory plane from a third time when the voltage on the select word line in the second memory plane starts ramping down from the bias voltage to the first supply voltage until a fourth time after the voltage on the select word line in the second memory plane is ramped down from the pass voltage to the first supply voltage.

In some implementations, in the last loop of the program operation on the first memory plane, before applying the bias voltage to the select word line, a post-pulse voltage is applied on the select word line of the word lines after applying the verify voltage on the select word line, the voltage on the select word line is ramped down from the post-pulse voltage to the first supply voltage, and the voltage on the select word line is immediately ramped up from the first supply voltage to the bias voltage.

In still another aspect, a system includes a memory device configured to store data, and a memory controller coupled to the memory device and configured to control the memory device. The memory device includes a first memory plane including memory cells and word lines respectively coupled to rows of the memory cells, and a peripheral circuit coupled to the first memory plane through the word lines. The peripheral circuit is configured to, in a last loop of a program operation on the first memory plane, after applying a verify voltage to a select word line of the word lines, ramp up a voltage on the select word line from a first supply voltage (Vdd) to a pass voltage, and ramp down the voltage on the select word line of the word lines from the pass voltage to the first supply voltage.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a memory device including peripheral circuits, according to some aspects of the present disclosure.

FIG. 2 illustrates a side view of a cross-section of a memory cell array including a NAND memory string, according to some aspects of the present disclosure.

FIG. 3 illustrates a block diagram of a memory device including a memory cell array and peripheral circuits, according to some aspects of the present disclosure.

FIG. 4 illustrates a schematic diagram of a memory device including multiple memory planes each including multiple blocks, according to some aspects of the present disclosure.

FIGS. 5A and 5B illustrate a waveform of word line voltages applied to a select word line in a program operation, according to some aspects of the present disclosure.

FIG. 6A illustrates timing diagrams of a program operation having multiple loops, according to some aspects of the present disclosure.

FIG. 6B illustrates timing diagrams of another program operation having multiple loops, according to some aspects of the present disclosure.

FIG. 7 illustrates a schematic timing diagram of a multi-plane program operation having multiple loops.

FIG. 8 illustrates a schematic timing diagram of a multi-plane program operation having multiple loops, according to some aspects of the present disclosure.

FIGS. 9A and 9B illustrate timing diagrams of a multi-plane program operation having multiple loops, according to some aspects of the present disclosure.

FIG. 10 illustrates timing diagrams of string drivers in the memory planes of FIGS. 9A and 9B, according to some aspects of the present disclosure.

FIG. 11 illustrates a schematic timing diagram of another multi-plane program operation having multiple loops, according to some aspects of the present disclosure.

FIG. 12 illustrates a flowchart of a method for programming a memory device, according to some aspects of the present disclosure.

FIG. 13 illustrates a flowchart of another method for programming a memory device, according to some aspects of the present disclosure.

FIG. 14 illustrates a block diagram of a system having a memory device, according to some aspects of the present disclosure.

FIG. 15A illustrates a diagram of a memory card having a memory device, according to some aspects of the present disclosure.

FIG. 15B illustrates a diagram of a solid-state drive (SSD) having a memory device, according to some aspects of the present disclosure.

The present disclosure will be described with reference to the accompanying drawings.

### DETAILED DESCRIPTION

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

Memory devices, such as NAND Flash memory devices, can store more than a single bit of information into each memory cell with multiple states in order to increase the storage capacity and reduce the cost per bit. The program operation of a NAND Flash memory device involves a number of program cycles and verify cycles. At the end of each verify cycle, all the word lines are recovered to the drain supply voltage Vdd, and the drain select gate (DSG) and source select gate (SSG) lines are recovered to the source supply voltage Vss, which can down-couple the channel potential, in particular, at the select NAND memory string programmed memory cell region close to the select word line. The down-coupled channel potential, however, can cause program disturbance in the subsequent program cycle due to the hot carrier injection (HCI) effect. To mitigate these issues, bias voltage(s) can be applied to the word lines close to the select word line at the beginning of the affected program cycle to clean the accumulated electrons in the channel in a so-called “pre-pulse period” in the program cycle. The additional pre-pulse period, however, prolongs the duration of the program cycle, thereby becoming the bottleneck of saving program time (t_{PROG}).

On the other hand, at the end of a verify cycle, failure bit count (FBC) needs to be performed in a reserved time period when all the word lines are recovered to Vdd. Some efforts have been made to merge the pre-pulse period in a program cycle and the FBC period in the preceding verify cycle into a “merged recovery/pre-pulse period” in order to reduce the total program time as well as the power consumption from the ramping up/down of the word line voltages.

For a memory device having multiple memory planes, different memory planes may be stopped at different times (e.g., undergoing different numbers of loops) in the same program operation due to various reasons, such as process and device variations between memory planes or program failure (not able to pass a certain verify level after the threshold number of program pulses) for one or more memory planes. However, for memory plane(s) that stop earlier in the merged recovery/pre-pulse period of the program operation, the voltages on the word lines will float at a positive bias voltage that can shift the threshold voltages of the programmed memory cells in the memory plane(s), as well as affect channel potential and introduce noise to the sensing current in the following read operations.

To address one or more of the aforementioned issues, the present disclosure provides a multi-plane program scheme that adds an additional period at the end of the program operation on those memory plane(s) that stop in the merged recovery/pre-pulse period of the program operation. The memory plane can perform operations similar to those in the pre-pulse period of verify cycle (thus also referred to as an “end pre-pulse period”), which can recover the voltages on the word lines from the positive bias voltages (e.g., greater than 2V) to a lower supply voltage (e.g., Vdd) to avoid threshold voltage shift, as well as clean the electrons accumulated in the channel due to the bias voltage, thereby resetting the channel potential. In some implementations, when adding the end pre-pulse period to the earlier-stopped memory plane(s), the remaining memory plane(s) that are still undergoing the program operation are temporarily disabled to avoid performing the same operations as the earlier-stopped memory plane(s) during the end pre-pulse period, thereby preventing down-coupling their channel potentials as described above. After the end pre-pulse period, the remaining memory plane(s) can be enabled to resume their operations in the merged recovery/pre-pulse period.

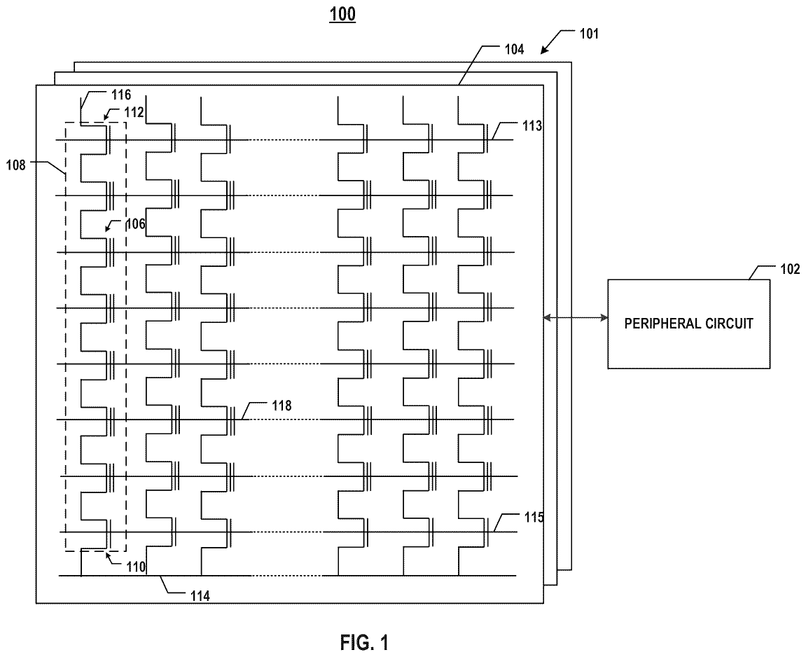

FIG. 1 illustrates a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge, which depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is an SLC that has two possible levels (memory states) and thus, can store one bit of data. For example, the first level “0” can correspond to a first range of threshold voltages, and the second level “1” can correspond to a second range of threshold voltages. In some implementations, each memory cell 106 is an xLC that is capable of storing more than a single bit of data in more than four levels. For example, the xLC may store two bits per cell (MLC), three bits per cell (TLC), or four bits per cell (QLC)). Each xLC can be programmed to assume a range of possible nominal storage values (i.e., corresponding to 2^{N} pieces of N-bits data). In some implementations, at least one of memory cells 106 is set to one of 2^{N} levels corresponding to a piece of N-bits data, where N is an integer greater than 1.

As shown in FIG. 1, each NAND memory string 108 can also include a source select gate (SSG) transistor 110 (a.k.a., bottom select gate (BSG) transistor) at its source end and a drain select gate (DSG) transistor 112 (a.k.a., top select gate (TSG) transistor) at its drain end. SSG transistor 110 and DSG transistor 112 can be configured to activate select NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. The drain of each NAND memory string 108 is coupled to a respective bit line 116 from which data can be read or written via an output bus (not shown), according to some implementations. In some implementations, each NAND memory string 108 is configured to be selected or deselected by applying a select voltage (e.g., a positive voltage greater than the threshold voltage of DSG transistor 112) or a deselect voltage (e.g., the ground voltage) to the gate of respective DSG transistor 112 through one or more DSG lines 113 and/or by applying a select voltage (e.g., a positive voltage greater than the threshold voltage of SSG transistor 110) or a deselect voltage (e.g., the ground voltage) to the gate of respective SSG transistor 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a select block 104, source lines 114 coupled to select block 104 as well as unselect blocks 104 in the same plane as select block 104 can be biased with an erase voltage (Vers), such as a high positive bias voltage (e.g., 20 V or more). Memory cells 106 of adjacent NAND memory strings 108 can be coupled through word lines 118 that select which row of memory cells 106 is affected by read and program operations. In some implementations, each word line 118 is coupled to a plurality of memory cells 106. Each word line 118 can include a plurality of control gates (gate electrodes) at each memory cell 106 and a gate line coupling the control gates.

As shown in FIG. 1, memory cell array 101 can include an array of memory cells 106 in a plurality of rows and a plurality of columns in each block 104. One column of memory cells corresponds to one NAND memory string 108, according to some implementations. The plurality of rows of memory cells 106 can be respectively coupled to word lines 118, and the plurality of columns of memory cells 106 can be respectively coupled to bit lines 116. Peripheral circuit 102 can be coupled to memory cell array 101 through bit lines 116 and word lines 118.

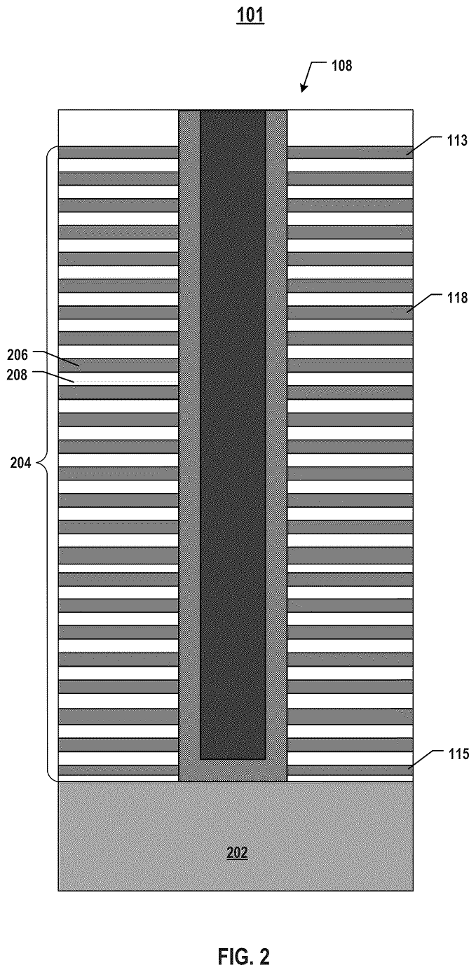

FIG. 2 illustrates a side view of a cross-section of memory cell array 101 including NAND memory string 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding memory cells 106, the gates of DSG transistors 112, or the gates of SSG transistors 110, and can extend laterally as DSG line 113 at the top of memory stack 204, SSG line 115 at the bottom of memory stack 204, or word line 118 between DSG line 113 and SSG line 115

As shown in FIG. 2, NAND memory string 108 includes a channel structure extending vertically through memory stack 204. In some implementations, the channel structure includes a channel hole filled with semiconductor material(s) (e.g., as a semiconductor channel) and dielectric material(s) (e.g., as a memory film). It is understood that although not shown in FIG. 2, additional components of memory cell array 101 can be formed including, but not limited to, gate line slits/source contacts, local contacts, interconnect layers, etc.

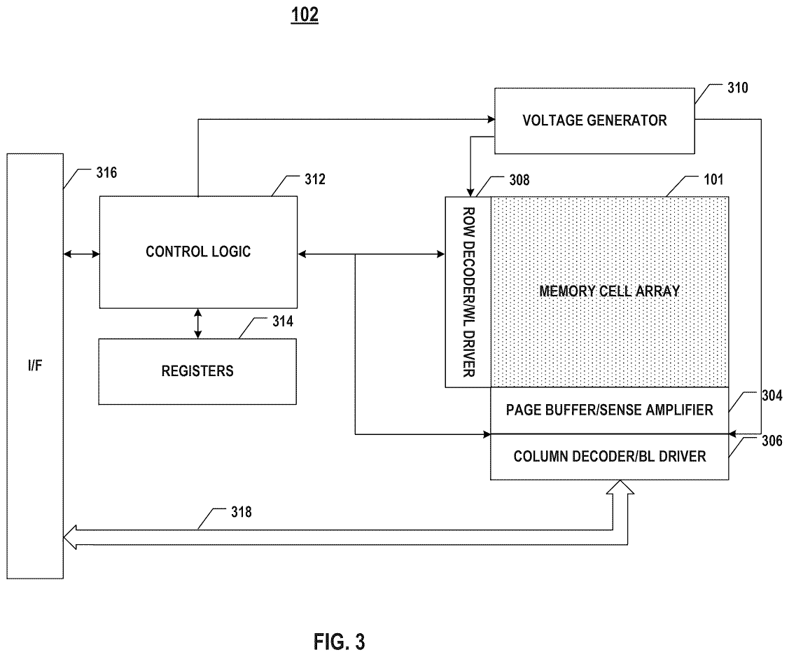

Referring back to FIG. 1, peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each select memory cell 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some exemplary peripheral circuits including a page buffer/sense amplifier 304, a column decoder/bit line driver 306, a row decoder/word line driver 308, a voltage generator 310, control logic 312, registers 314, an interface (I/F) 316, and a data bus 318. It is understood that in some examples, additional peripheral circuits not shown in FIG. 3 may be included as well.

Page buffer/sense amplifier 304 can be configured to sense (read) and program (write) data from and to memory cell array 101 according to the control signals from control logic 312. In one example, page buffer/sense amplifier 304 may store one or more pages of program data (write data, referred to herein as “data page”) to be programmed. In another example, page buffer/sense amplifier 304 may verify programmed select memory cells 106 in each program/verify cycle in a program operation to ensure that the data has been properly programmed into memory cells 106 coupled to select word lines 118. In still another example, page buffer/sense amplifier 304 may also sense the low power signals from bit line 116 that represents a data bit stored in memory cell 106 and amplify the small voltage swing to recognizable logic levels in a read operation.

Column decoder/bit line driver 306 can be configured to be controlled by control logic 312 and select one or more NAND memory strings 108 by applying bit line voltages generated from voltage generator 310. Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Voltage generator 310 can be configured to be controlled by control logic 312 and generate the word line voltages (e.g., read voltage, program voltage, channel pass voltage, local voltage, verify voltage, etc.), bit line voltages, and source line voltages to be supplied to memory cell array 101.

Control logic 312 can be coupled to each peripheral circuit described above and configured to control the operations of each peripheral circuit. Registers 314 can be coupled to control logic 312 and include status registers, command registers, and address registers for storing status information, command operation codes (OP codes), and command addresses for controlling the operations of each peripheral circuit. Interface 316 can be coupled to control logic 312 and act as a control buffer to buffer and relay control commands received from a memory controller (not shown) and/or a host (not shown) to control logic 312 and status information received from control logic 312 to the memory controller and/or the host. Interface 316 can also be coupled to column decoder/bit line driver 306 via data bus 318 and act as a data input/output (I/O) interface and a data buffer to buffer and relay the data to and from memory cell array 101.

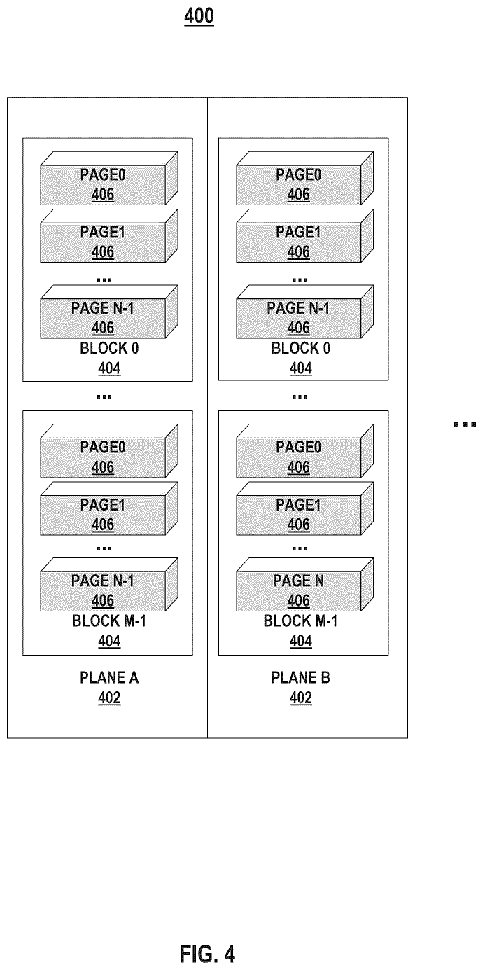

FIG. 4 illustrates a schematic diagram of a memory device 400 including multiple memory planes 402 each including multiple blocks, according to some aspects of the present disclosure. Memory device 400 may be an example memory device 100 in FIG. 1. As shown in FIG. 4, memory device 400 can include a plurality of memory planes 402, such as a Plane A (PLA) and a Plane B (PLB). Each memory plane 402 can include a plurality of blocks 404, such as M blocks (Block 0 to Block M−1). Block 404 may be an example of block 104 in FIG. 1. Each block 404 can include a plurality of pages 406, such as N pages (Page 0 to Page N−1). Each page 406 may correspond to memory cells 106 coupled to one word line 118, a portion of one word line 118, or multiple word lines 118, as shown in FIG. 1. In some implementations, each memory plane 402 includes memory cells 106 and word lines 118 respectively coupled to rows of memory cells 106.

In a program operation that applies to memory device 400, each memory plane 402 can be operated in parallel, following the same timing by the same control instructions. In some implementations, a respective block 404 (e.g., Block 0) in each memory plane 402 is programmed in parallel by the same program operation.

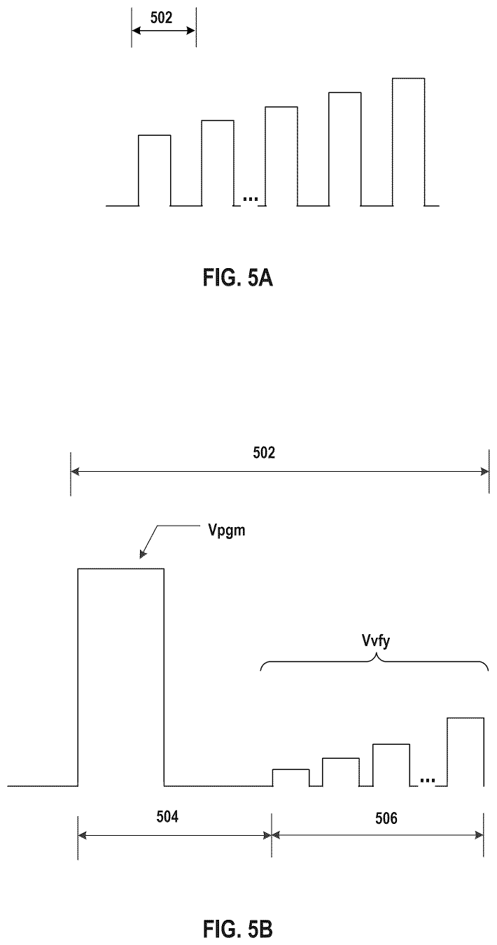

To perform a program operation, in addition to page buffer/sense amplifier 304 providing to each select memory cell 106 the corresponding piece of data, row decoder/word line driver 308 can be configured to apply program voltages and verify voltages to a select word line 118 coupled to a select row of memory cells 106 in one or more program/verify cycles in order to raise the threshold voltage of each select memory cell 106 to a desired level (into a desired range of threshold voltages) based on the corresponding piece of data. For example, FIGS. 5A and 5B illustrate a waveform of word line voltages applied to a select word line in a program operation, according to some aspects of the present disclosure.

As shown in FIGS. 5A and 5B, the program operation includes one or more loops 502, each of which includes a program cycle 504 and a verify cycle 506, according to some implementations. As shown in FIG. 5B, in each loop 502, row decoder/word line driver 308 can be configured to apply a program voltage (Vpgm) on select word line 118 to select row of memory cells 106 in program cycle 504 and sequentially apply one or more verify voltages (Vvfy) with incremental changes of voltage levels to verify select row of memory cells 106 in verify cycle 506. That is, in each loop 502, peripheral circuit 102 can perform verification of select row of memory cells 106 at one or more levels in verify cycle 506 after applying a program voltage in program cycle 504. The number of verify voltages applied in verify cycle 506 depends on the level being programmed by the specific loop 502, according to some implementations. As a result, at the end of the program operation, for example, select memory cell 106 may be programmed into one of the 2^{N} levels based on the corresponding N bits of data to be stored in select memory cell 106, where N is a positive integer. In some implementations, the program operation is an incremental step pulse program (ISPP), which gradually increases the program voltage on a step-voltage basis in different loops 502. The magnitude of this “step” (e.g., the increase in magnitude of the program voltage in each loop 502 relative to the program voltage in the immediately previous loop 502) is known as the “pulse step height.”

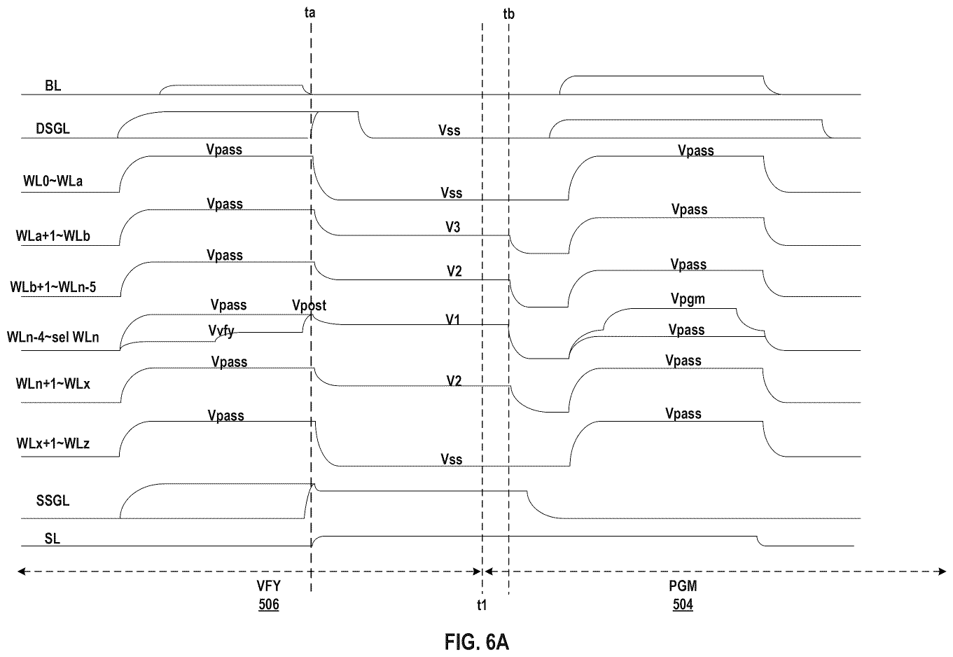

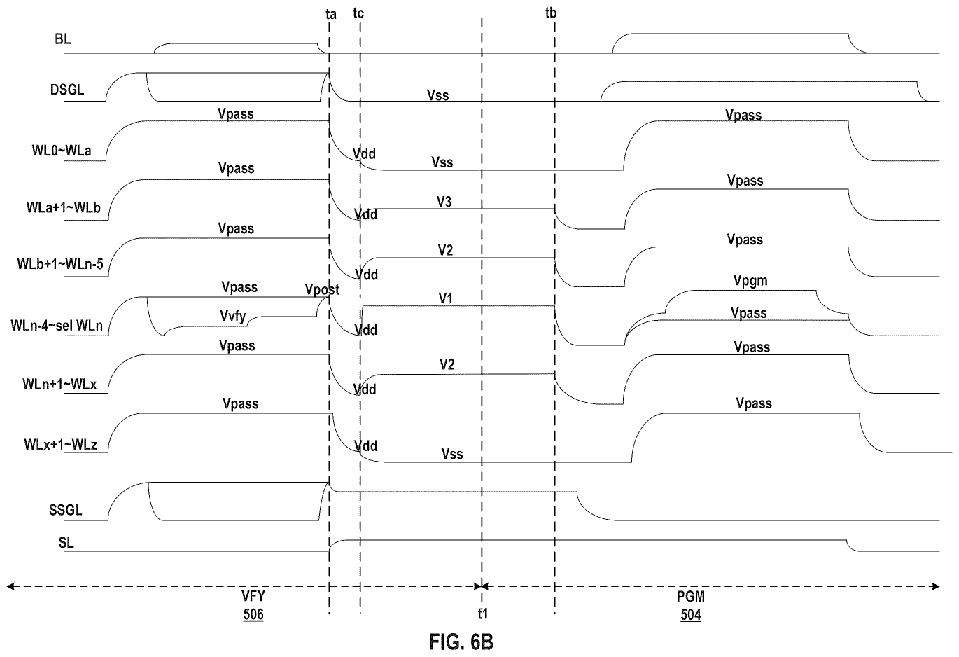

FIG. 6A illustrates timing diagrams of a program operation having multiple loops, according to some aspects of the present disclosure. The program operation can include a plurality of loops (e.g., N loops). Each loop of the program operation can include a program cycle and a verify cycle, as described above in FIGS. 5A and 5B. FIG. 6A shows verify cycle 506 (VFY) in a first loop and program cycle 504 (PGM) in a second loop immediately after the first loop. It is understood that the “first loop” does not have to be the very first loop in the program operation as long as there is another loop, e.g., the “second loop,” immediately afterward. Verify cycle 506 can include a verify period (phase) in which a verify voltage (Vvfy) having one or more verify voltage pulses is applied on the select word line (sel WLn) to verify select memory cells coupled to the select word line at one or more levels. At the end of the verify period (e.g., a time ta in FIG. 6A), a post-pulse voltage (Vpost) can be applied on the select word line. In the verify period, a pass voltage (Vpass) can be applied on each unselect word line. The pass voltage can be greater than the threshold voltages of the unselect memory cells, such that the channels of the selected NAND memory strings become conductive in the verify period. In some implementations, the pass voltage is greater than the verify voltage, such that at the end of the verify period, for example, at the time ta in FIG. 6A, the voltage on the select word line is up-coupled/boosted to the post-pulse voltage, which is the same as the pass voltage.

After the verify period of verify cycle 506, the voltage on each word line can be ramped down to a respective bias voltage (V1, V2, or V3) or a supply voltage (Vss, e.g., ground voltage 0V). For example, the voltage on each of the select word line and the first group of unselect word lines (WLn−4-sel WLn) may be ramped down from the post-pulse voltage or the pass voltage to the first bias voltage (V1), the voltage on each of the second group of unselect word lines (WLb+1-WLn−5, and WLn+1-WLx) may be ramped down from the pass voltage to the second bias voltage (V2), the voltage on each of the third group of unselect word lines (WLa+1-WLb) may be ramped down from the pass voltage to the third bias voltage (V3), and the voltage on each of the fourth group of unselect word lines (WL0-WLa, and WLx+1-WLz) may be ramped down from the pass voltage to the supply voltage (Vss).

As shown in FIG. 6A, the voltage on each word line can be ramped down and then maintained at the respective bias voltage or the supply voltage (Vss) in a time period from time ta in verify cycle 506 in the first loop to another time tb in program cycle 504 in the second loop, which can be viewed as a merged recovery/pre-pulse period across verify cycle 506 and program cycle 504.

As shown in FIG. 6A, program cycle 504 can include a program period (phase) after the merged recovery/pre-pulse period in which a program voltage (Vpgm) having one or more program voltage pulses is applied to the select word line to program the select memory cells to one or more levels. In the program period, the pass voltage can be applied to each unselect word line.

FIG. 6B illustrates timing diagrams of another program operation having multiple loops, according to some aspects of the present disclosure. The program operation can include a plurality of loops (e.g., N loops). Each loop of the program operation can include a program cycle and a verify cycle, as described above in FIGS. 5A and 5B. FIG. 6B shows verify cycle 506 (VFY) in a first loop and program cycle 504 (PGM) in a second loop immediately after the first loop. It is understood that the “first loop” does not have to be the very first loop in the program operation as long as there is another loop, e.g., the “second loop,” immediately afterward. Verify cycle 506 can include a verify period (phase) in which a verify voltage (Vvfy) having one or more verify voltage pulses is applied on the select word line (sel WLn) to verify select memory cells coupled to the select word line at one or more levels. At the end of the verify period (e.g., time ta in FIG. 6B), a post-pulse voltage (Vpost) can be applied on the select word line. In the verify period, a pass voltage (Vpass) can be applied on each unselect word line. The pass voltage can be greater than the threshold voltages of the unselect memory cells, such that the channels of the selected NAND memory strings become conductive in the verify period. In some implementations, the pass voltage is greater than the verify voltage, such that at the end of the verify period, for example, at time ta in FIG. 6B, the voltage on the select word line is up-coupled/boosted to the post-pulse voltage, which is the same as the pass voltage.

Different from FIG. 6A, in FIG. 6B, after the verify period of verify cycle 506, the voltage on the select word line can be ramped down from the post-pulse voltage to another supply voltage (Vdd), instead of the first bias voltage (V1), and then immediately ramped up from the supply voltage (Vdd) to the first bias voltage. In some implementations, the first bias voltage (e.g., about 4.5V) is greater than the supply voltage (Vdd, e.g., about 2V). Similarly, after the verify period of verify cycle 506, the voltage on each unselect word line can be ramped down from the pass voltage to the supply voltage (Vdd), instead of the respective bias voltage (V1, V2, or V3) or the supply voltage (Vss), and then immediately ramped up from the supply voltage (Vdd) to the respective bias voltage (V1, V2, or V3) or the supply voltage (Vss). In some implementations, the bias voltages (e.g., between 2V and 5V) are greater than the supply voltage (Vdd, e.g., about 2V), which is greater than the supply voltage (Vss, e.g., ground voltage 0V). For example, the voltage on each of the select word line and a first group of unselect word lines (WLn−4-sel WLn) may be ramped up from the supply voltage (Vdd) to the first bias voltage (V1), the voltage on each of a second group of unselect word lines (WLb+1- WLn−5, and WLn+1-WLx) may be ramped up from the supply voltage (Vdd) to the second bias voltage (V2), the voltage on each of a third group of unselect word lines (WLa+1-WLb) may be ramped up from the supply voltage (Vdd) to the third bias voltage (V3), and the voltage on each of a fourth group of unselect word lines (WL0-WLa, and WLx+1-WLz) may be ramped down from the supply voltage (Vdd) to the supply voltage (Vss).

As shown in FIG. 6B, the voltage on each word line can be ramped up/down and then maintained at the respective bias voltage or the supply voltage (Vss) in a time period from time tc in verify cycle 506 in the first loop to another time tb in program cycle 504 in the second loop, which can be viewed as a merged recovery/pre-pulse period across verify cycle 506 and program cycle 504.

Similar to FIG. 6A, as shown in FIG. 6B, program cycle 504 can include a program period (phase) after the merged recovery/pre-pulse period in which a program voltage (Vpgm) having one or more program voltage pulses is applied to the select word line to program the select memory cells to one or more levels. In the program period, the pass voltage can be applied to each unselect word line.

When a program operation having multiple loops is applied to memory device 400 having multiple memory planes 402 (i.e., a multi-plane program operation having multiple loops), different memory planes 402 may undergo different numbers of loops 502 due to various reasons. In one example, it may take different numbers of loops to program memory cells to the desired levels in different memory planes 402 due to the fabrication process and device variation among the different memory planes 402. Memory plane 402 that finishes the program operation by a smaller number of loops may be referred to herein as a “fast plane.” In another example, one or more memory planes 402 may still not be able to pass a certain verify level after the maximum number of program pulses (program failure). Memory plane 402 that stops the program operation prematurely due to program failure may be referred to herein as a “failed plane.” The fast plane and failed plane may be referred to herein as “earlier-stopped planes.”

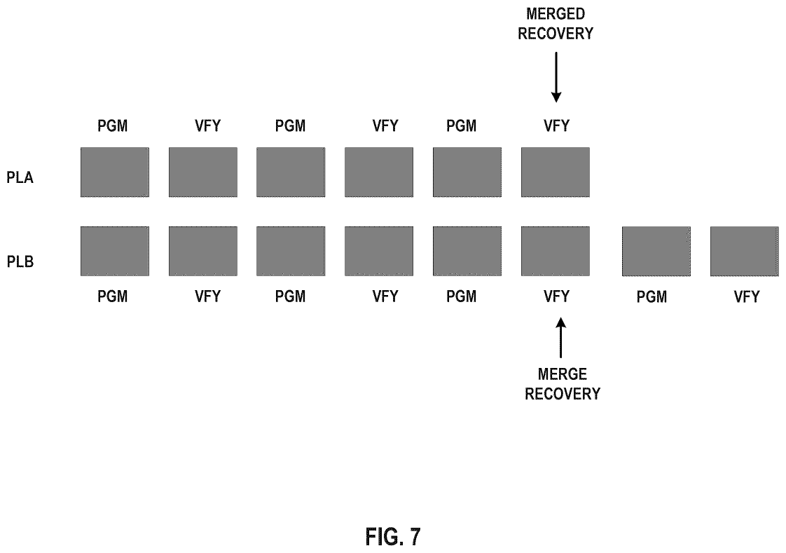

For example, as shown in FIG. 7, Plane A (PLA) represents an earlier-stopped plane, which may stop the program operation on Plane A after the third loop, while Plane B (PLB) may stop the same program operation on Plane B after the fourth loop, because Plane A may be a fast plane or a failed plane. In other words, when Plane A stops the program operation after the third loop, Plane B may continue the program operation thereon. For Plane A, the last verify cycle (VFY) may include a merged recovery/pre-pulse period (“merged recovery” in FIG. 7) in which the program operation stops. For example, the program operation on Plane A may stop at time t1 in the merged recovery/pre-pulse period between ta and tb in FIG. 6A or in the merged recovery/pre-pulse period between tc and tb in FIG. 6B. The voltages on the select word lines and some unselect word lines when the program operation on Plane A stops may be at positive bias voltages (e.g., V1, V2, and V3 in FIGS. 6A and 6B), which may be floated until the program operation on Plane B stops after one or more loops. As a result, the threshold voltages of the programmed memory cells in Plane A may be shifted, and noise may be introduced to the sensing current in the subsequent read operation.

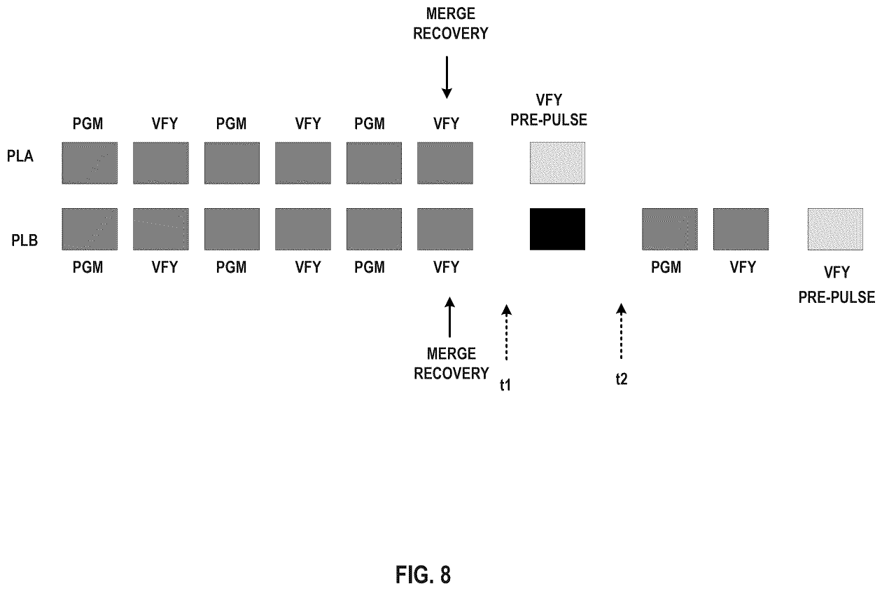

To address the threshold voltage shift and sensing current noise issues in multi-plane program operations having multiple loops and merged recovery/pre-pulse period, an end pre-pulse period can be added to the end of the program operation on an earlier-stopped plane, which can recover the voltages on the word lines from the higher positive bias voltages to a lower supply voltage (e.g., Vdd) and reset the channel potential. On the other hand, when adding the end pre-pulse period to the earlier-stopped plane, the remaining memory plane(s) that are still undergoing the program operation can be temporarily disabled to avoid performing the same operations as the earlier-stopped plane during the end pre-pulse period, thereby preventing down-coupling their channel potentials. After the end pre-pulse period, the remaining memory plane(s) can be enabled to resume their operations in the merged recovery/pre-pulse period. For example, FIG. 8 illustrates a schematic timing diagram of a multi-plane program operation having multiple loops, according to some aspects of the present disclosure.

As shown in FIG. 8, peripheral circuit 102 is configured to start the multi-plane program operation on a first memory plane (PLA) and a second memory plane (PLB) at the same time and stop the multi-plane program operation on the first memory plane before the second memory plane, for example, because the first memory plane is a fast plane or a failed plane, according to some implementations. Different from the example in FIG. 7 in which the earlier-stopped plane stops the program operation after the last verify cycle in the merged recovery/pre-pulse period, as shown in FIG. 8, in some implementations, peripheral circuit 102 is configured to perform additional operations on the earlier-stopped first memory plane in an end pre-pulse period (“verify pre-pulse” in FIG. 8) after the verify cycle of the last loop of the first memory plane (e.g., between a first time t1 and a second time t2 in FIG. 8) to recover word line voltages to a lower level and reset channel potential. In some implementations, peripheral circuit 102 is also configured to suspend the program operation on the second memory plane during the end pre-pulse period between the first and second times t1 and t2 to avoid interference to the planned operations on the second memory plane in its merged recovery/pre-pulse period (“merged recovery” in FIG. 8.) In some implementations, peripheral circuit 102 is further configured to resume the program operation on the second memory plane after the end pre-pulse period of the first memory plane (the second time t2). That is, the earlier-stopped first memory plane can stop the program operation after the end pre-pulse period, instead of the merged recovery/pre-pulse period, and the second memory plane can be temporarily disabled during the end pre-pulse period of the first memory plane and can be enabled again after the program operation on the first memory plane stops. In some implementations, peripheral circuit 102 is also configured to perform additional operations on the second memory plane in an end pre-pulse period (“verify pre-pulse” in FIG. 8) at the end of the verify cycle of the last loop of the second memory plane as well to recover word line voltages to a lower level and reset channel potential.

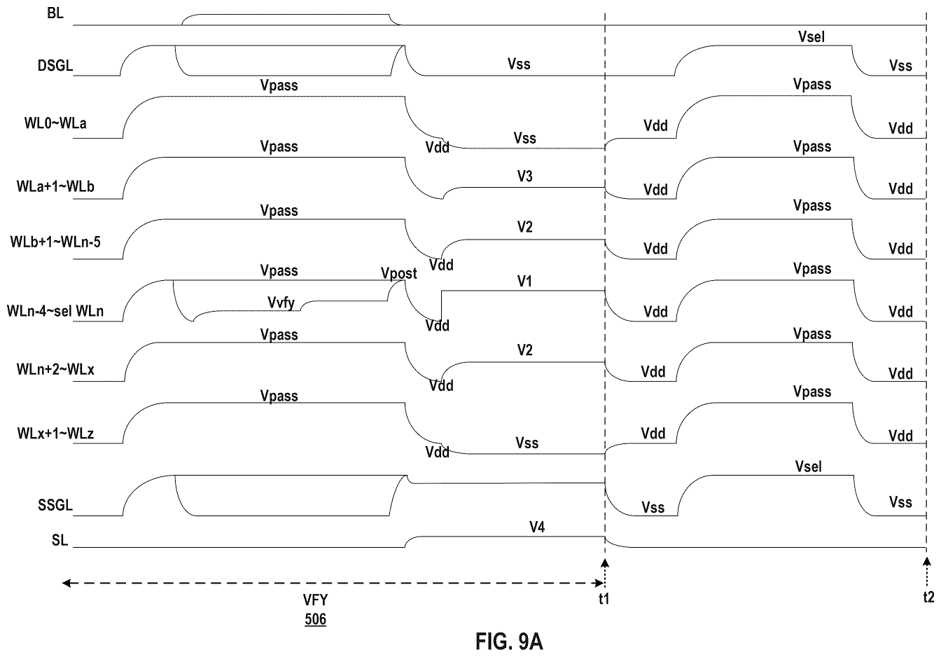

FIGS. 9A and 9B illustrate timing diagrams of a multi-plane program operation having multiple loops, according to some aspects of the present disclosure. For example, FIG. 9A illustrates an example of the multi-plane program operation performed on the earlier-stopped first memory plane (PLA in FIG. 8), and FIG. 9B illustrates an example of the multi-plane program operation performed on the second memory plane (PLB in FIG. 8). The program operation can include a plurality of loops. Each loop of the program operation can include a program cycle and a verify cycle, as described above in FIGS. 5A, 5B, and 8. As described above in FIG. 8, the number of loops of the program operation performed on the first memory plane is smaller than the number of loops of the program operation performed on the second memory plane because the first memory plane is a fast plane or a failed plane, according to some implementations. In some implementations, FIG. 9A illustrates verify cycle 506 in the last loop of the program operation on the first memory plane (e.g., the third loop in FIG. 8), while FIG. 9B illustrates verify cycle 506 in a non-last loop of the program operation on the second memory plane that is performed at the same time as the last loop of the program operation on the first memory plane (e.g., the third loop in FIG. 8), as well as program cycle 504 of another loop immediately after the non-last loop of the program operation on the second memory plane (e.g., the fourth loop in FIG. 8).

In some implementations, verify cycle 506 in FIGS. 9A and 9B includes a verify period (phase) in which word line driver 308 of peripheral circuit 102 is configured to apply a verify voltage (Vvfy) having one or more verify voltage pulses on a select word line (sel WLn) to verify select memory cells coupled to the select word line at one or more levels. At the end of the verify period, word line driver 308 of peripheral circuit 102 is configured to apply a post-pulse voltage (Vpost) on the select word line, according to some implementations. For example, the voltage on the select word line may be ramped up from the verify voltage to the post-pulse voltage. In some implementations, in the verify period, word line driver 308 of peripheral circuit 102 is also configured to apply a pass voltage (Vpass) to each unselect word line. The pass voltage can be greater than the threshold voltages of the unselect memory cells, such that the channels of the selected NAND memory strings become conductive in the verify period. In some implementations, the pass voltage is greater than the verify voltage, such that at the end of the verify period the voltage on the select word line is up-coupled/boosted to the post-pulse voltage, which is the same as the pass voltage.

In some implementations, verify cycle 506 also includes a merged recovery/pre-pulse period after the verify period. In the merged recovery/pre-pulse period, word line driver 308 of peripheral circuit 102 can be further configured to ramp down the voltage on the select word line from the post-pulse voltage to a first supply voltage (Vdd), and then immediately ramp up the voltage on the select word line from the first supply voltage to a first bias voltage (V1). That is, the voltage on the select word line can be ramped down from the post-pulse voltage to the first supply voltage, for example, using a first voltage source (e.g., a drain voltage source). To immediately ramp up the voltage on the select word line, word line driver 308 of peripheral circuit 102 can be configured to ramp up the voltage on the select word line as soon as the voltage on the select word line reaches the first supply voltage.

Similarly, in the merged recovery/pre-pulse period, word line driver 308 of peripheral circuit 102 can be further configured to ramp down the voltage on each unselect word line from the pass voltage to the same first supply voltage (Vdd), and then immediately ramp up the voltage on the unselect word line from the first supply voltage to a respective bias voltage (e.g., V1, V2, or V3) or a second supply voltage (Vss). That is, the voltage on the unselect word line can be ramped down from the pass voltage to the first supply voltage using the same first voltage source (e.g., a drain voltage source). To immediately ramp up the voltage on the unselect word line, word line driver 308 of peripheral circuit 102 can be configured to ramp up the voltage on the unselect word line as soon as the voltage on the unselect word line reaches the first supply voltage. In some implementations, the voltages on the select word line and the unselect word lines are ramped down from the same first time and ramped up from the same second time.

The unselect word lines can be categorized into different groups depending on their distances from the select word line and the program direction of the word lines, and different bias voltages (e.g., V1, V2, and V3) can be assigned to different groups of unselect word lines to form a bias voltage distribution to better clean the channels before the next program period. In some implementations, the first bias voltage is greater than the second bias voltage, which is greater than the third bias voltage, which is, in turn, greater than the second supply voltage (Vss), i.e., V1>V2>V3>Vss. For example, the first bias voltage may be about 4.5V, the second bias voltage may be about 3.5V, the third bias voltage may be about 2.5V, and the second supply voltage may be 0V. In other words, the closer to the select word line, the greater the bias voltage is assigned to the unselect word line group, according to some implementations.

In some implementations as shown in FIGS. 9A and 9B in which the program direction is from the bit line (BL) to the source line (SL), e.g., from top to bottom, the voltage on each of the select word line and a first group of unselect word lines (WLn−4-sel WLn) is ramped down from the first supply voltage (Vdd) to the first bias voltage (V1) using a first bias voltage regulator, the voltage on each of a second group of unselect word lines (WLb+1-WLn−5, and WLn+1-WLx) is ramped down from the first supply voltage (Vdd) to the second bias voltage (V2) using a second bias voltage regulator, the voltage on each of a third group of unselect word lines (WLa+1-WLb) is ramped down from the first supply voltage (Vdd) to the third bias voltage (V3) using a third bias voltage regulator, and the voltage on each of a fourth group of unselect word lines (WL0-WLa, and WLx+1-WLz) is ramped down from the first supply voltage (Vdd) to the second supply voltage (Vss) using a second voltage source (e.g., a source voltage source). As shown in FIGS. 9A and 9B, word line driver 308 of peripheral circuit 102 can be further configured to maintain the voltage on each of the select word line and unselect word line on the respective bias voltage (e.g., V1, V2, or V3) or second supply voltage (Vss) in the merged recovery/pre-pulse period. In other words, the bias voltages or the second supply voltage can be maintained on the word lines in the merged recovery/pre-pulse period.

In some implementations, as shown in FIGS. 9A and 9B in which the program direction is from the bit line to the source line, word line driver 308 of peripheral circuit 102 is further configured to ramp down the voltage on the DSG line (DSGL) from a select voltage to the second supply voltage (Vss) smaller than the first supply voltage (Vdd) to turn off the DSG transistors coupled to the DSG line. The select voltage can be higher than the threshold voltage of the DSG transistors, such that the DSG transistors can be switched from on to off in the merged recovery/pre-pulse period. The voltages on the select word line and the DSG line can be ramped down from the same first time until the same second time. In some implementations, in the merged recovery/pre-pulse period, word line driver 308 of peripheral circuit 102 is further configured to ramp up the voltage on the source line to a fourth bias voltage (V4) since the program direction in FIG. 9A is from the bit line to the source line.

Although not shown, it is understood that in some examples in which the program direction is from the source line to the bit line, e.g., from bottom to top, in the merged recovery/pre-pulse period, the voltage on each of the select word line and a first group of unselect word lines (sel WLn-WLn+4) may be ramped down from first supply voltage (Vdd) to the first bias voltage (V1) using a first bias voltage regulator, the voltage on each of a second group of unselect word lines (WLa+1-WLn−1, and WLn+5-WLx) may be ramped down from first supply voltage (Vdd) to the second bias voltage (V2) using a second bias voltage regulator, the voltage on each of a third group of unselect word lines (WLx+1-WLy) may be ramped down from first supply voltage (Vdd) to the third bias voltage (V3) using a third bias voltage regulator, and the voltage on each of a fourth group of unselect word lines (WL0-WLa, and WLy+1-WLz) may be ramped down from first supply voltage (Vdd) to the second supply voltage (Vss) using the second voltage source (e.g., a source voltage source). Movere, the voltage on the SSG line (SSGL) may be ramped down from a select voltage to the second supply voltage (Vss) smaller than the first supply voltage (Vdd) to turn off the SSG transistors coupled to the SSG line. The select voltage can be higher than the threshold voltage of the SSG transistors, such that the SSG transistors can be switched from on to off in the merged recovery/pre-pulse period. In the merged recovery/pre-pulse period, the voltage on the bit line may be ramped up to a fourth bias voltage (V4) when the program direction is from the source line to the bit line.

It is understood that the operations performed in the merged recovery/pre-pulse period are not limited to the example described above with respect to FIGS. 9A and 9B. For example, in some examples, the operation performed in the merged recovery/pre-pulse period as described above with respect to FIG. 6A may be performed by the multi-plane program operation as well. That is, the voltages on each word line may be ramped down from the pass voltage or the post-pulse voltage to the respective bias voltage or the second supply voltage (Vss) directly without first being ramped down together to the first supply voltage (Vdd).

As shown in FIG. 9A, in some implementations, verify cycle 506 is in the last loop of the multi-plane program operation on the first memory plane, which is stopped at a first time t1, since the first memory plane is an earlier-stopped plane. An end-pre-pulse period between the first time t1 and a second time t2 can be added after the verify cycle 506 in the last loop. In the end pre-pulse period, word line driver 308 of peripheral circuit 102 is configured to ramp down the voltage on the select word line from the first bias voltage (V1) to the first supply voltage (Vdd), according to some implementations. Word line driver 308 of peripheral circuit 102 can also be configured to ramp up the voltage on the select word line from the first supply voltage to the pass voltage (Vpass), maintain the voltage on the select word line at the pass voltage for a while, and then ramp down the voltage on the select word line from the pass voltage back to the first supply voltage. Similarly, in the end pre-pulse period, word line driver 308 of peripheral circuit 102 is configured to ramp down/up the voltage on each unselect select word line from the respective bias voltage (V1, V2, or V3) or the second supply voltage (Vss) to the first supply voltage (Vdd), according to some implementations. Word line driver 308 of peripheral circuit 102 can also be configured to ramp up the voltage on each unselect word line from the first supply voltage to the pass voltage (Vpass), maintain the voltage on each unselect word line at the pass voltage for a while, and then ramp down the voltage on each unselect word line from the pass voltage back to the first supply voltage. In some implementations, the pass voltage is greater than the bias voltage, and the bias voltages are greater than the first supply voltage. That is, the bias voltages can be between the first supply voltage and the pass voltage.

As shown in FIG. 9A, in some implementations, in the end pre-pulse period, word line driver 308 of peripheral circuit 102 is further configured to ramp up the voltage on each select gate line (DSG line or SSG line) from the second supply voltage (Vss) to a select voltage (Vsel) to turn on the respective select gate transistor (DSG transistor and or SSG transistor) at the same time when the voltage on each word line is ramped up. The select voltage can be greater than the threshold voltages of the select gate transistors. Word line driver 308 of peripheral circuit 102 can be further configured to maintain the voltage on each select gate line at the select voltage for a while when the voltage on each word line is maintained at the pass voltage, and then ramp down the voltage on each select gate line from the select voltage back to the second supply voltage at the same time when the voltage on each word line is ramped down.

The multi-plane program operation on the first memory plane can then stop at the second time t2 when the voltage on each word line is at the first supply voltage (Vdd), instead of at a higher bias voltage (V1, V2, or V3), and the voltage on each select word line is at the second supply voltage (Vss). Thus, even the multi-plane program operation may continue on the second memory plane, the voltage on each select word line is floated at a relatively low supply voltage (Vdd) to avoid shifting the threshold voltages of the programmed memory cells in the first memory plane, according to some implementations. Moreover, in the end pre-pulse period, when the voltage on each word line is ramped up to and maintained at the pass voltage and each select gate line is ramped up to and maintained at the select voltage, the channel becomes conductive to be reset, according to some implementations.

As shown in FIG. 9B, in some implementations, verify cycle 506 is in a non-last loop of the multi-plane program operation on the second memory plane, which is not stopped at the first time t1, since the second memory plane is not an earlier-stopped plane. To avoid the operations performed on the first memory plane during the end pre-pulse period between the first and second times t1 and t2 described above in FIG. 9A are to be performed on the second memory plane, peripheral circuit 102 can be configured to suspend the multi-plane program operation on the second memory plane from the first time t1 until the second time t2 (i.e., throughout the end pre-pulse period of the first memory plane). As shown in FIG. 9B, in some implementations, the voltage on each word line is floated during the suspended period between the first time t1 until the second time t2, for example, at the respective bias voltage (V1, V2, or V3) or the second supply voltage (Vss). Peripheral circuit 102 can be further configured to resume the multi-plane program operation on the second memory plane at the second time t2 when the multi-plane program operation on the first memory plane stops.

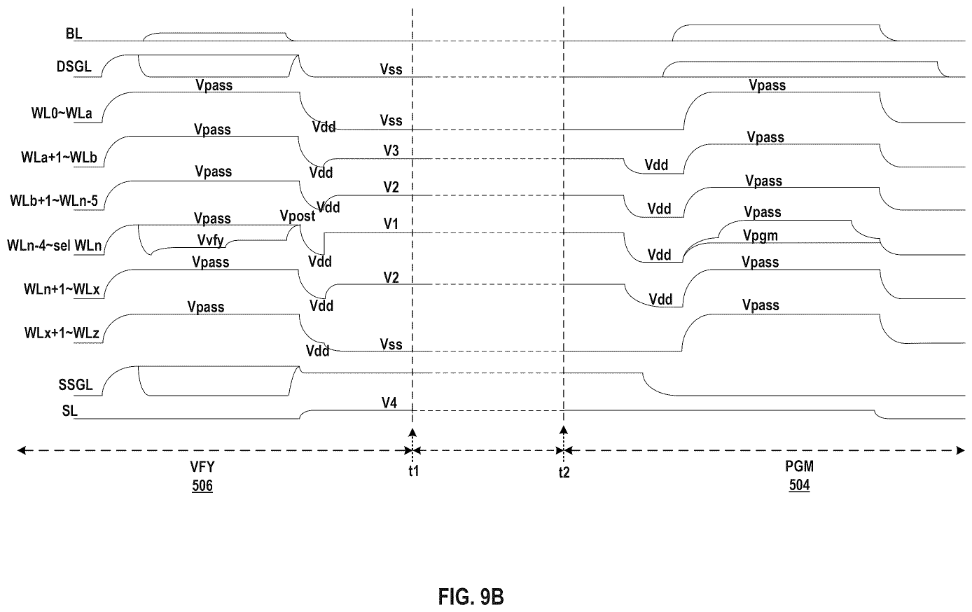

The suspension of the second memory plane can be controlled by string drivers of peripheral circuit 102. For example, FIG. 10 illustrates timing diagrams of string drivers in the memory planes of FIGS. 9A and 9B, according to some aspects of the present disclosure. Word line driver 308 of peripheral circuit 102 can include a plurality of string drivers each coupled to a respective word line or a select gate line to control the respective voltage applied thereon in response to a respective control signal. As shown in FIG. 10, word line driver 308 of peripheral circuit 102 of the first memory plane can include string drivers (PLA string driver) each including a driving transistor. The drain of the driving transistor is coupled to a respective word line or select gate line (WL/SGL) of the second memory plane, the source of the driving transistor is coupled to a respective local word line or local select gate line (LWL/LSGL) of the second memory plane, and the gate of the driving transistor is coupled to a decoder and configured to receive a respective control signal (VXD_PLA) of the second memory plane. Similarly, word line driver 308 of peripheral circuit 102 of the second memory plane can include string drivers (PLB string driver) each including a driving transistor. The drain of the driving transistor is coupled to a respective word line or select gate line (WL/SGL) of the second memory plane, the source of the driving transistor is coupled to a respective local word line or local select gate line (LWL/LSGL) of the second memory plane, and the gate of the driving transistor is coupled to a decoder and configured to receive a respective control signal (VXD_PLB) of the second memory plane. Each driving transistor can be a p-type transistor or an N-type transistor.

As shown in FIG. 10, between the first and second times t1 and t2 (the end pre-pulse period of the first memory plane), by setting the control signal of the second memory plane (VXD_PLB) at the low level (logic “0”), the string drivers of the second memory plane (PLB string driver) can be configured to be disabled to float the voltages on the word lines and select gate lines in the second memory plane (e.g., as shown in FIG. 9B). In contrast, by setting the control signal of the first memory plane (VXD_PLA) at the high level (logic “1”), the string drivers of the first memory plane (PLA string driver) can be configured to be enabled to perform the operations during the end pre-pulse period of the first memory plane (e.g., as shown in FIG. 9A). At the second time 2, the control signal of the second memory plane can be switched to the high level (logic “1”) to enable the string drivers of the second memory plane to resume the multi-plane program operation on the second memory plane, while the control signal of the first memory plane can be switched to the low level (logic “0”) to disable the string drivers of the first memory plane to stop the multi-plane program operation on the first memory plane.

Referring back to FIG. 9B, the multi-plane program operation on the second memory plane can be resumed at the second time t2. Program cycle 504 in the next loop immediately after the non-last loop can include, after the merged recovery/pre-pulse period, a program period (phase) in which word line driver 308 of peripheral circuit 102 can be further configured to apply a program voltage (Vpgm) having one or more program voltage pulses on the select word line to program the select memory cells to one or more levels. In the program period, word line driver 308 of peripheral circuit 102 can also be configured to apply the pass voltage on each unselect word line to make the channels conductive for programming.

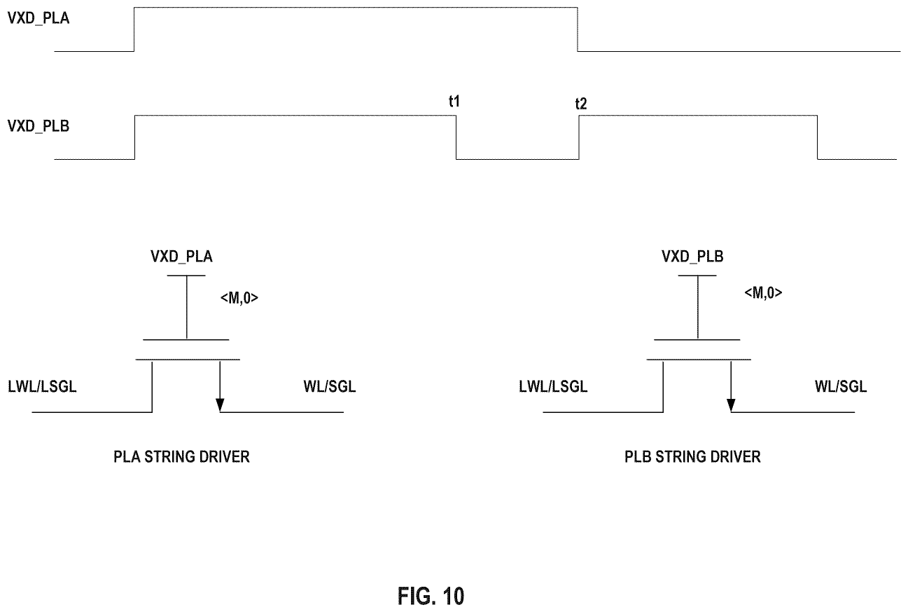

Although the multi-plane program operation is described above with respect to two memory planes (first memory plane PLA and second memory plane PLB) in FIG. 8, it is understood that the same scheme may be applied to a memory device including more than two memory planes, such as three memory planes. For example, FIG. 11 illustrates a schematic timing diagram of another multi-plane program operation having multiple loops, according to some aspects of the present disclosure.

As shown in FIG. 11, peripheral circuit 102 is configured to start the multi-plane program operation on a first memory plane (PLA), a second memory plane (PLB), and a third memory plane (PLC) at the same time and stop the multi-plane program operation on the first memory plane before the second memory plane, and stop the multi-plane program operation on the second memory plane before the third memory plane, for example, because the first and second memory planes are fast planes or failed planes, according to some implementations. In some implementations, peripheral circuit 102 is configured to perform additional operations on the earliest-stopped first memory plane in an end pre-pulse period (“verify pre-pulse” in FIG. 11) after the verify cycle of the last loop of the first memory plane (e.g., between a first time t1 and a second time t2 in FIG. 11) to recover word line voltages to a lower level and reset channel potential. In some implementations, peripheral circuit 102 is also configured to suspend the program operation on the second memory plane, as well as on the third memory plane, during the end pre-pulse period between the first and second times t1 and t2 to avoid interference to the planned operations on the second and third memory planes in their merged recovery/pre-pulse period (“merged recovery” in FIG. 11.) In some implementations, peripheral circuit 102 is further configured to resume the multi-plane program operation on the second memory plane and the third memory plane after the end pre-pulse period of the first memory plane (the second time t2). That is, the earliest-stopped first memory plane can stop the program operation after its end pre-pulse period, instead of the merged recovery/pre-pulse period, and the second and third memory planes can be temporarily disabled during the end pre-pulse period of the first memory plane and can be enabled again after the program operation on the first memory plane stops.

In some implementations, peripheral circuit 102 is further configured to perform additional operations on the earlier-stopped second memory plane in an end pre-pulse period (“verify pre-pulse” in FIG. 11) after the verify cycle of the last loop of the second memory plane (e.g., between a third time t3 and a fourth time t4 in FIG. 11) to recover word line voltages to a lower level and reset channel potential. In some implementations, peripheral circuit 102 is further configured to suspend the program operation on the third memory plane during the end pre-pulse period between the third and fourth times t3 and t4 to avoid interference to the planned operations on the third memory plane in its merged recovery/pre-pulse period (“merged recovery” in FIG. 11.) In some implementations, peripheral circuit 102 is further configured to resume the program operation on the third memory plane after the end pre-pulse period of the second memory plane (the fourth time t4). That is, the earlier-stopped second memory plane can stop the program operation after its end pre-pulse period, instead of the merged recovery/pre-pulse period, and the third memory plane can be temporarily disabled during the end pre-pulse period of the second memory plane again and can be enabled again after the program operation on the second memory plane stops.

In some implementations, peripheral circuit 102 is further configured to perform additional operations on the third memory plane in an end pre-pulse period (“verify pre-pulse” in FIG. 11) at the end of the verify cycle of the last loop of the third memory plane as well to recover word line voltages to a lower level and reset channel potential.

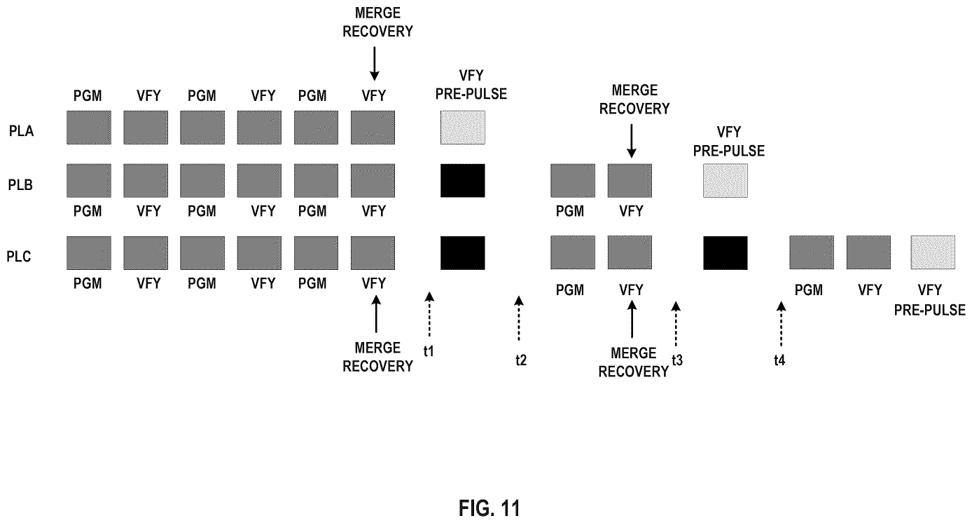

FIG. 12 illustrates a flowchart of a method 1200 for programming a memory device, according to some aspects of the present disclosure. The memory device may be any suitable memory device disclosed herein, such as memory device 400. Method 1200 may be implemented by peripheral circuit 102, such as row decoder/word line driver 308, page buffer/sense amplifier 304, and control logic 312. It is understood that the operations shown in method 1200 may not be exhaustive and that other operations can be performed as well before, after, or between any of the illustrated operations. Further, some of the operations may be performed simultaneously, or in a different order than shown in FIG. 12.

Referring to FIG. 12, method 1200 starts at operation 1202, in which a program operation is started on a first memory plane, a second memory plane, and a third memory plane at a same time. In some implementations, the program operation is stopped on the first memory plane before the second memory plane, and is stopped on the second memory plane before the third memory plane. For example, as shown in FIG. 11, a multi-plane program operation is started at the same time on PLA, PLB, and PLC. The multi-plane program operation is stopped first on PLA, then on PLB, and lastly on PLC.

Method 1200 proceeds to operation 1204, as illustrated in FIG. 12, in which the program operation is suspended on the second memory plane and the third memory plane from a first time to a second time. In some implementations, to suspend the program operation on the second and third memory planes, the string drivers of the second and third memory planes are disabled to float the voltages on the word lines in the second and third memory planes. For example, as shown in FIG. 11, the multi-plane program operation is suspended on both PLB and PLC from t1 to t2 in which PLA is undergoing its end pre-pulse period.

Method 1200 proceeds to operation 1206, as illustrated in FIG. 12, in which the program operation is suspended on the third memory plane from a third time to a fourth time. In some implementations, to suspend the program operation on the third memory plane, the string drivers of the third memory plane are disabled to float the voltages on the word lines in the third memory plane. For example, as shown in FIG. 11, the multi-plane program operation is suspended on PLC from t3 to t4 again in which PLB is undergoing its end pre-pulse period.

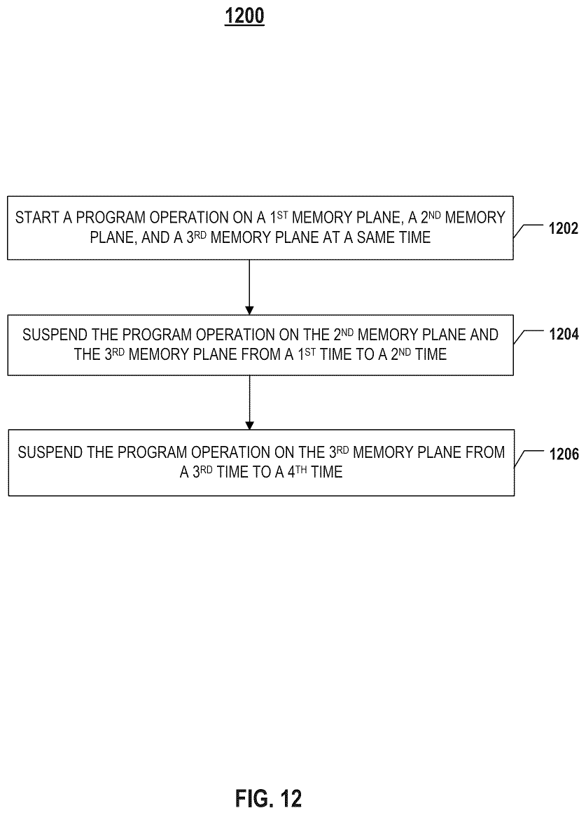

FIG. 13 illustrates a flowchart of another method 1300 for programming a memory device, according to some aspects of the present disclosure. The memory device may be any suitable memory device disclosed herein, such as memory device 400. Method 1300 may be implemented by peripheral circuit 102, such as row decoder/word line driver 308, page buffer/sense amplifier 304, and control logic 312. It is understood that the operations shown in method 1300 may not be exhaustive and that other operations can be performed as well before, after, or between any of the illustrated operations. Further, some of the operations may be performed simultaneously, or in a different order than shown in FIG. 13.

Referring to FIG. 13, method 1300 starts at operation 1302, in which after applying a verify voltage to a select word line, a bias voltage is applied to a select word line. For example, as shown in FIG. 9A, in verify cycle 506 of the last loop of an earlier-stopped plane, the verify voltage (Vvfy) is applied to the select word line. After that, the first bias voltage (V1) is applied to the select word line in the merged recovery/pre-pulse period of verify cycle 506.

In some implementations, before applying the bias voltage to the select word line, a post-pulse voltage is applied on the select word line of the word lines after applying the verify voltage on the select word line, the voltage on the select word line is ramped down from the post-pulse voltage to the first supply voltage, and the voltage on the select word line is immediately ramped up from the first supply voltage to the bias voltage. For example, as shown in FIG. 9A, in the merged recovery/pre-pulse period of verify cycle 506, after applying the verify voltage (Vvfy) on the select word line, a post-pulse voltage (Vpost) is applied on the select word line. The voltage on the select word line is then ramped down from the post-pulse voltage to the first supply voltage (Vdd), and then immediately ramped up from the first supply voltage to the first bias voltage (V1).

Method 1300 proceeds to operation 1304, as illustrated in FIG. 13, in which the voltage on the select word line is ramped down from the bias voltage to a first supply voltage. For example, as shown in FIG. 9A, from the first time t1 in the end pre-pulse period, the voltage on the select word line is ramped down from the first bias voltage (V1) to the first supply voltage (Vdd).

Method 1300 proceeds to operation 1306, as illustrated in FIG. 13, in which the voltage on the select word line is ramped up from the first supply voltage to a pass voltage. In some implementations, the bias voltage is between the first supply voltage and the pass voltage. For example, as shown in FIG. 9A, the voltage on the select word line is ramped up from the first supply voltage (Vdd) to the pass voltage (Vpass), and then maintained at the pass voltage for a while.

Method 1300 proceeds to operation 1308, as illustrated in FIG. 13, in which a voltage on a select gate line is ramped up from a second supply voltage smaller than the first supply voltage to a select voltage. For example, as shown in FIG. 9A, the voltage on the DSG line or the SSG line is ramped up from the first supply voltage (Vdd) to the select voltage (Vsel), and then maintained at the select voltage for a while, during the same time when the voltage on the select word line is ramped up from the first supply voltage to the pass voltage, and then maintained at the pass voltage for a while.

Method 1300 proceeds to operation 1310, as illustrated in FIG. 13, in which the voltage on the select word line is ramped down from the pass voltage to the first supply voltage. For example, as shown in FIG. 9A, the voltage on the select word line is ramped down from the pass voltage (Vpass) to the first supply voltage (Vdd).

Method 1300 proceeds to operation 1312, as illustrated in FIG. 13, in which the voltage on the select gate line is ramped down from the select voltage to the second supply voltage. For example, as shown in FIG. 9A, the voltage on the DSG line or the SSG line is ramped down from the select voltage (Vsel) to the second supply voltage (Vss).

As described above with respect to FIGS. 8 and 10, for a non earlier-stopped plane (e.g., PLB in FIG. 8 and PLC in FIG. 11), in the last loop of the multi-program operation performed thereon, an end pre-pulse period can be added at the end in the same way as the end pre-pulse period of an earlier-stopped plane, to refresh its channels and recover the word line voltages to a lower level. In some implementations, a program voltage is applied to the select word line in the second memory plane (the non earlier-stopped plane) after the second time when the voltage on the select word line in the first memory plane (the earlier-stopped plane) is ramped down from the pass voltage to the first supply voltage. For example, as shown in FIG. 9B, in program cycle 504 after the second time t2, the program voltage (Vpgm) is applied to the select word line. In some implementations, in the last loop of the program operation on the second memory plane (the non earlier-stopped plane), after applying a verify voltage to the select word line, the bias voltage is applied to the select word line, the voltage on the select word line is ramped down from the bias voltage to the first supply voltage, the voltage on the select word line is ramped up from the first supply voltage to the pass voltage, and the voltage on the select word line is ramped down from the pass voltage to the first supply voltage. For example, the operations between the first and second times t1 and t2 on the first memory plane in FIG. 9A may be similarly applied to the second memory plane in the last loop of the program operation on the second memory plane.

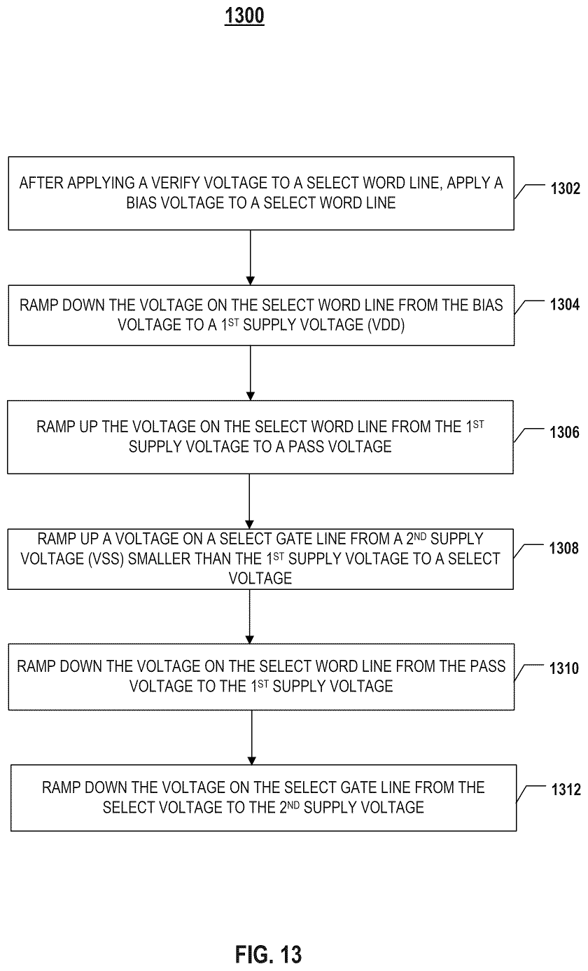

FIG. 14 illustrates a block diagram of a system 1400 having a memory device, according to some aspects of the present disclosure. System 1400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 14, system 1400 can include a host 1408 and a memory system 1402 having one or more memory devices 100 (shown in FIG. 1) and a memory controller 1406. Host 1408 can be a processor of an electronic device, such as a central processing unit (CPU), or a system-on-chip (SoC), such as an application processor (AP). Host 1408 can be configured to send or receive data to or from memory devices 100.

Memory device 100 can be any memory device disclosed in the present disclosure. Memory controller 1406 is coupled to memory device 100 and host 1408 and is configured to control memory device 100, according to some implementations. Memory controller 1406 can manage the data stored in memory device 100 and communicate with host 1408. In some implementations, memory controller 1406 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1406 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1406 can be configured to control operations of memory device 100, such as read, erase, and program operations. Memory controller 1406 can also be configured to manage various functions with respect to the data stored or to be stored in memory device 100 including, but not limited to bad-block management, garbage collection, logical-to-physical address conversion, wear leveling, etc. In some implementations, memory controller 1406 is further configured to process error correction codes (ECCs) with respect to the data read from or written to memory device 100. Any other suitable functions may be performed by memory controller 1406 as well, for example, formatting memory device 100. Memory controller 1406 can communicate with an external device (e.g., host 1408) according to a particular communication protocol. For example, memory controller 1406 may communicate with the external device through at least one of various interface protocols, such as a USB protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

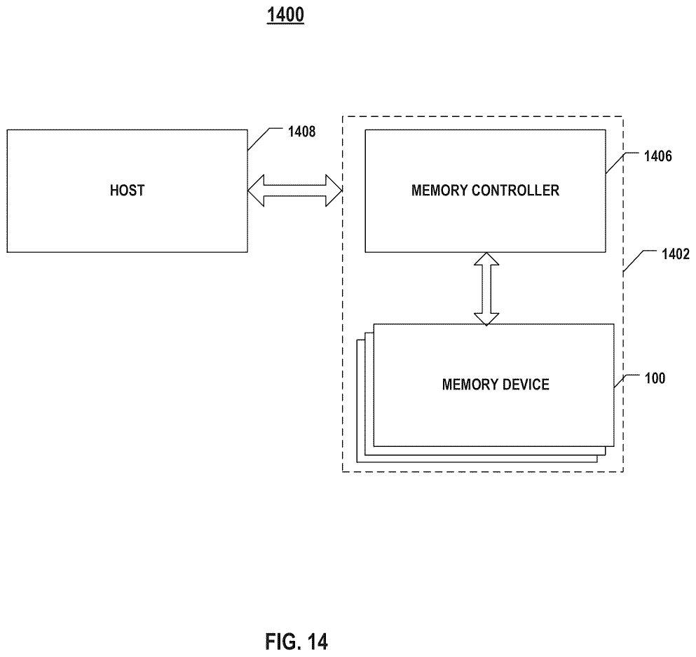

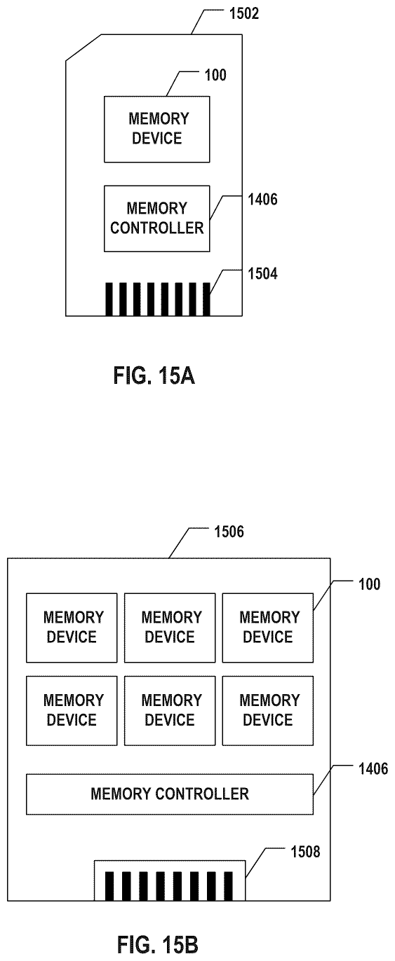

Memory controller 1406 and one or more memory devices 100 can be integrated into various types of storage devices, for example, being included in the same package, such as a universal Flash storage (UFS) package or an eMMC package. That is, memory system 1402 can be implemented and packaged into different types of end electronic products. In one example as shown in FIG. 15A, memory controller 1406 and a single memory device 100 may be integrated into a memory card 1502. Memory card 1502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1502 can further include a memory card connector 1504 coupling memory card 1502 with a host (e.g., host 1408 in FIG. 14). In another example as shown in FIG. 15B, memory controller 1406 and multiple memory devices 100 may be integrated into an SSD 1506. SSD 1506 can further include an SSD connector 1508 coupling SSD 1506 with a host (e.g., host 1408 in FIG. 14). In some implementations, the storage capacity and/or the operation speed of SSD 1506 is greater than those of memory card 1502.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

Although specific configurations and arrangements are discussed, it should be understood that this is done for illustrative purposes only. As such, other configurations and arrangements can be used without departing from the scope of the present disclosure. Also, the subject matter as described in the present disclosure can also be used in a variety of other applications. Functional and structural features as described in the present disclosures can be combined, adjusted, modified, and rearranged with one another and in ways that are consistent with the scope of the present disclosure.

What is claimed is:

1. A memory device, comprising:
a first memory plane comprising memory cells and word lines respectively coupled to rows of the memory cells; and
a peripheral circuit coupled to the first memory plane through the word lines and configured to, in a last loop of a program operation on the first memory plane:
after applying a verify voltage to a select word line of the word lines, ramp up a voltage on the select word line from a first supply voltage (Vdd) to a pass voltage; and
ramp down the voltage on the select word line of the word lines from the pass voltage to the first supply voltage.

2. The memory device of claim 1, wherein the peripheral circuit is further configured to, in the last loop of the program operation on the first memory plane:
after applying the verify voltage to the select word line, apply a bias voltage to the select word line, the bias voltage being between the first supply voltage and the pass voltage; and
ramp down the voltage on the select word line from the bias voltage to the first supply voltage before ramping up the voltage on the select word line from the first supply voltage to the pass voltage.

3. The memory device of claim 1, wherein
the first memory plane further comprises:
select gate transistors respectively coupled to columns of the memory cells; and
a select gate line coupled to the select gate transistors;
the peripheral circuit is coupled to the first memory plane through the select gate line and further configured to, in the last loop of the program operation on the first memory plane:
ramp up a voltage on the select gate line from a second supply voltage (Vss) smaller than the first supply voltage to a select voltage; and
ramp down the voltage on the select gate line from the select voltage to the second supply voltage.

4. The memory device of claim 2, further comprising:
a second memory plane comprising memory cells and word lines respectively coupled to rows of the memory cells,
wherein the peripheral circuit is coupled to the first memory plane and the second memory plane and configured to start the program operation on the first memory plane and the second memory plane at a same time, and stop the program operation on the first memory plane before the second memory plane.

5. The memory device of claim 4, wherein the peripheral circuit is configured to suspend the program operation on the second memory plane from a first time when the voltage on the select word line in the first memory plane starts ramping down from the bias voltage to the first supply voltage until a second time when the voltage on the select word line in the first memory plane is ramped down from the pass voltage to the first supply voltage.

6. The memory device of claim 5, wherein
the peripheral circuit comprises string drivers respectively coupled to the word lines in the second memory plane; and
to suspend the program operation on the second memory plane, the string drivers are configured to be disabled to float voltages on the word lines in the second memory plane.

7. The memory device of claim 5, wherein the peripheral circuit is further configured to apply a program voltage to the select word line of the word lines in the second memory plane after the second time.

8. The memory device of claim 5, wherein the peripheral circuit is further configured to, in a last loop of the program operation on the second memory plane:
after applying a verify voltage to the select word line, apply the bias voltage to the select word line;
ramp down the voltage on the select word line from the bias voltage to the first supply voltage;
ramp up the voltage on the select word line from the first supply voltage to the pass voltage; and
ramp down the voltage on the select word line from the pass voltage to the first supply voltage.

9. The memory device of claim 8, further comprising:
a third memory plane,
wherein the peripheral circuit is coupled to the first memory plane, the second memory plane, and the third memory plane and configured to start the program operation on the first memory plane, the second memory plane, and the third memory plane at a same time, and stop the program operation on the second memory plane before the third memory plane.

10. The memory device of claim 9, wherein the peripheral circuit is configured to:
suspend the program operation on the third memory plane from the first time when the voltage on the select word line in the first memory plane starts ramping down from the bias voltage to the first supply voltage until the second time after the voltage on the select word line in the first memory plane is ramped down from the pass voltage to the first supply voltage; and
suspend the program operation on the third memory plane from a third time when the voltage on the select word line in the second memory plane starts ramping down from the bias voltage to the first supply voltage until a fourth time after the voltage on the select word line in the second memory plane is ramped down from the pass voltage to the first supply voltage.

11. The memory device of claim 2, wherein the peripheral circuit is further configured to, in the last loop of the program operation on the first memory plane, before applying the bias voltage to the select word line:
apply a post-pulse voltage on the select word line of the word lines after applying the verify voltage on the select word line;
ramp down the voltage on the select word line from the post-pulse voltage to the first supply voltage; and
immediately ramp up the voltage on the select word line from the first supply voltage to the bias voltage.

12. A method for operating a memory device, the memory device comprising a first memory plane comprising memory cells and word lines respectively coupled to rows of the memory cells, the method comprising, in a last loop of a program operation on the first memory plane:
after applying a verify voltage to a select word line of the word lines, ramping up a voltage on the select word line from a first supply voltage (Vdd) to a pass voltage; and
ramping down the voltage on the select word line of the word lines from the pass voltage to the first supply voltage.

13. The method of claim 12, further comprising, in the last loop of the program operation on the first memory plane:
after applying the verify voltage to the select word line, applying a bias voltage to the select word line, the bias voltage being between the first supply voltage and the pass voltage; and
ramping down the voltage on the select word line from the bias voltage to the first supply voltage before ramping up the voltage on the select word line from the first supply voltage to the pass voltage.

14. The method of claim 12, wherein
the first memory plane further comprises select gate transistors respectively coupled to columns of the memory cells, and a select gate line coupled to the select gate transistors; and
the method further comprises, in the last loop of the program operation on the first memory plane:
ramping up a voltage on the select gate line from a second supply voltage (Vss) smaller than the first supply voltage to a select voltage; and
ramping down the voltage on the select gate line from the select voltage to the second supply voltage.

15. The method of claim 13, wherein
the memory device further comprises a second memory plane comprising memory cells and word lines respectively coupled to rows of the memory cells; and
the method further comprises:
starting the program operation on the first memory plane and the second memory plane at a same time; and
stopping the program operation on the first memory plane before the second memory plane.

16. The method of claim 15, further comprising suspending the program operation on the second memory plane from a first time when the voltage on the select word line in the first memory plane starts ramping down from the bias voltage to the first supply voltage until a second time when the voltage on the select word line in the first memory plane is ramped down from the pass voltage to the first supply voltage.

17. The method of claim 16, wherein
the memory device further comprises string drivers respectively coupled to the word lines in the second memory plane; and
suspending the program operation on the second memory plane comprises disabling the string drivers to float voltages on the word lines in the second memory plane.

18. The method of claim 16, further comprising:
applying a program voltage to the select word line of the word lines in the second memory plane after the second time.

19. The method of claim 13, further comprising, in the last loop of the program operation on the first memory plane, before applying the bias voltage to the select word line:
applying a post-pulse voltage on the select word line of the word lines after applying the verify voltage on the select word line;
ramping down the voltage on the select word line from the post-pulse voltage to the first supply voltage; and
immediately ramping up the voltage on the select word line from the first supply voltage to the bias voltage.

20. A system, comprising:
a memory device configured to store data and comprising:
a first memory plane comprising memory cells and word lines respectively coupled to rows of the memory cells; and
a peripheral circuit coupled to the first memory plane through the word lines and configured to, in a last loop of a program operation on the first memory plane:
after applying a verify voltage to a select word line of the word lines, ramp up a voltage on the select word line from a first supply voltage (Vdd) to a pass voltage; and
ramp down the voltage on the select word line of the word lines from the pass voltage to the first supply voltage; and
a memory controller coupled to the memory device and configured to control the memory device.
